(19) United States
(12) Patent Application Publication
(10) Pub. No.: US 2019/0067061 A1
(43) Pub. Date: Feb. 28, 2019

(54) RIGID CARRIER ASSEMBLIES HAVING AN INTEGRATED ADHESIVE FILM

(71) Applicant: Daewon Semiconductor Packaging Industrial Company, Santa Clara, CA (US)

(72) Inventors: Sunna Chang, Santa Clara, CA (US); John Kim, Santa Clara, CA (US); Ryan Park, Santa Clara, CA (US); Matthew Whitlock, Santa Clara, CA (US); Athens Okoren, Santa Clara, CA (US)

(21) Appl. No.: 16/116,075

(22) Filed: Aug. 29, 2018

Related U.S. Application Data
(60) Provisional application No. 62/551,751, filed on Aug. 29, 2017.

(51) Int. Cl. H01L 21/673; H01L 23/60

(52) U.S. Cl. CPC H01L 21/67336; H01L 23/60

(57) ABSTRACT

Introduced here are carrier trays that include an adhesive film affixed to a deck area. For example, the adhesive film may be integrally laminated onto the top surface of the carrier tray as a single continuous (i.e., unbroken) sheet. The adhesive film may substantially conform to the top surface of the carrier tray. Semiconductor component(s) can be secured to the carrier tray based on the adhesiveness of the adhesive film. Said another way, proper securement of the semiconductor component(s) to the carrier tray may depend on the tackiness of the constituent material(s) of the adhesive film.

### CROSS-REFERENCE TO RELATED APPLICATIONS

This application claims priority to U.S. Provisional Application No. 62/551,751, titled “Carrier Assemblies for Integrated Circuits Having an Integrated Adhesive Film Tape” and filed on Aug. 29, 2017, which is incorporated by reference herein in its entirety.

### RELATED FIELD

The present technology relates to carrier assemblies for protecting semiconductor components and, more specifically, to rigid trays having an integrated adhesive film for holding the semiconductor components in place.

### BACKGROUND

Several different configurations have been used to facilitate the transportation of semiconductor components (e.g., semiconductor wafers or semiconductor dies) between different manufacturing/testing sites, namely, stick magazines, injection-molded trays, and carrier tapes. For example, carriers often transport semiconductor components from one location to another location to facilitate the manufacture of integrated circuits (ICs) from the semiconductor components. This is especially true for carriers who are members of the Joint Electron Device Engineering Council (JEDEC), which has established standards for safe handling, transport, and storage of ICs, modules, and other semiconductor components.

Stick magazines (also referred to as a “shipping tubes”) can be used to transport and store semiconductor components between the manufacturing site and the assembly site. Stick magazines are also used to feed semiconductor components to automatic-placement machines for surface mounting and through-hole mounting.

Injection-molded trays contain semiconductor components during component-assembly operations, during transport from the manufacturing site to the assembly site, and when feeding the semiconductor components to automatic-placement machines for surface mounting on board assemblies. Shipping trays are typically designed for semiconductor components that have leads on four sides (e.g., Quad Flat Package (QFP) and thin QFP (TQFP) packages) and that require lead isolation during shipping, handling, or processing.

Carrier tape can be used for transport from the manufacturing site to the assembly site, as well as storage at the assembly site. Carrier tape (which is often wound around a reel) is designed for feeding semiconductor components to automatic-placement machines for surface mounting on board assemblies.

However, these configurations exhibit several limits on, for example, the optimum quantity of semiconductor components per square area due to the limits of individual component retention, the lateral movement during the manufacturing/testing processes due to the design limitations of individual punched cavities (which can contribute to unwanted semiconductor components being inadvertently damaged from handling), etc. Such limitations lead to low manufacturing/handling capacity and high testing costs.

### BRIEF DESCRIPTION OF THE DRAWINGS

Various features of the technology will become more apparent to those skilled in the art from a study of the Detailed Description in conjunction with the drawings. Embodiments of the technology are illustrated by way of example and not limitation in the drawings, in which like references may indicate similar elements.

FIG. 1 depicts an example of a carrier tray that includes a continuous deck area laminated with an adhesive film.

FIG. 2 illustrates a vertical section view of the carrier tray taken along line B of FIG. 1.

FIG. 3 illustrates a horizontal sectional view of the carrier tray taken along line A of FIG. 1.

FIG. 4 includes an exploded view of multiple carrier trays stacked for handling, transport, and/or storage of semiconductor components.

FIG. 5 includes a top plane view of a carrier tray that includes a deck area on which an adhesive film has been mounted.

FIG. 6 includes a sectional view depicting the pre-forming of a carrier tray that includes a deck area and an adhesive film.

FIG. 7 includes a top plan view of a carrier tray showing how an adhesive film can be laminated along a deck area set within a rim that extends around a periphery of the carrier tray.

FIG. 8 includes a sectional view of the layers of a pre-formed carrier tray and an adhesive film that is integrally mounted along a deck area.

FIG. 9 is a flowchart of a process for transporting semiconductor component(s) using the carrier trays described herein.

FIG. 10 is a flowchart of a process for manufacturing the carrier trays described herein.

The drawings depict various embodiments for the purpose of illustration only. Those skilled in the art will recognize that alternative embodiments may be employed without departing from the principles of the technology. Accordingly, while specific embodiments are shown in the drawings, the technology is amenable to various modifications.

### DETAILED DESCRIPTION

One option for facilitating the handling, transport, and storage of semiconductor components is a carrier tray. Carrier trays are used to restrict the movement of semiconductor components during transport. A carrier tray may be designed specifically to protect, for example, semiconductor wafers, which are generally thin and circular. Conventional carrier trays restrict the movement of the semiconductor components stored therein during transport by maintaining physical contact with the semiconductor components.

Carrier trays may be utilized to transport semiconductor components between multiple facilities during the semiconductor manufacturing and testing processes. Moreover, carrier trays may be utilized to store semiconductor components within a storage facility before, during, or after such processes. Carrier trays prevent semiconductor components from coming into contact with one another, thereby preventing damage to the semiconductor components. Carrier trays may be used to present the semiconductor components to a manual placement tool or an automatic placement tool (also referred to as a “pick-and-place machine”) for testing, component dicing, etc. Component dicing may dice the semiconductor component (e.g., a wafer), and utilize a portion of the semiconductor component in the fabrication of an integrated circuit.

Carrier trays can be used in the semiconductor industry in the transport of semiconductor components because carrier trays reliably protect the semiconductor components from damage during transport. However, conventional carrier trays exhibit several limitations that restrict their ability to provide adequate protection to sensitive semiconductor components. For example, carrier trays have historically been produced via an injection molding process. However, an injection-molded carrier tray may inadvertently damage a semiconductor component due to an external force applied to part(s) of the injection-molded carrier tray in contact with the semiconductor component. The injection-molded carrier tray may also fail to properly dissipate static electricity, which can lead to further damage to the semiconductor components disposed thereon due to electrostatic discharge (ESD). Such limitations can lead to damaged semiconductor components, greater transport costs, and lower efficiency in semiconductor component manufacturing and testing.

Introduced here, therefore, are plastic, injection-molded tray (PIMT) carrier assemblies (or simply “carrier assemblies”) designed to address the limitations of conventional carrier trays. Examples of semiconductor components include semiconductor wafers (e.g., singulated wafer or diced wafer), semiconductor dies (i.e., bumped die or bare die), and other electronic components used in the fabrication of integrated circuits (ICs). Certain embodiments have been described in the context of semiconductor wafers for the purpose of illustration only. Those skilled in the art will recognize the carrier tray assemblies introduced here could be used in the handling, transport, and/or storage of any type of semiconductor component.

Carrier assemblies can be provided with an adhesive film integrated along the tray deck by adhesion (e.g., through lamination). In some embodiments, the adhesive film is bonded along a flat, plan area of the tray deck as a single continuous sheet. Semiconductor component(s) can be secured to the carrier assembly based on the adhesiveness of the adhesive film. Said another way, proper securement of the semiconductor component(s) to the carrier assembly may depend on the tackiness of the constituent material(s) of the adhesive film.

Semiconductor components can be detached from the adhesive film of the carrier assembly either manually or automatically (i.e., by a computer-implemented system, such as a pick-and-place robotic system). Thus, the semiconductor components may be readily separated when transported to a manufacturing process or a testing process, though the semiconductor components may remain stable when the carrier assembly is rotated along the x-axis, y-axis, or z-axis relative to the application.

An object of the present invention is to provide a simple, reliable, and quick method of securing semiconductor components to a carrier assembly. A semiconductor component may use the tray deck as the positioning/seating plane upon which semiconductor component(s) can be secured. Such technology enables the carrier assembly to be rotated and moved laterally without displacing or damaging the semiconductor components.

Additional information on the manufacturing of adhesive films, as well as the placement of semiconductor components, can be found in U.S. application Ser. No. ______, titled “Tape Carrier Assemblies having an Integrated Adhesive Film,” which is incorporated by reference herein in its entirety.

### Terminology

References in this description to “an embodiment” or “one embodiment” means that the particular feature, function, structure, or characteristic being described is included in at least one embodiment. Occurrences of such phrases do not necessarily refer to the same embodiment, nor are they necessarily referring to alternative embodiments that are mutually exclusive of one another.

Unless the context clearly requires otherwise, the words “comprise” and “comprising” are to be construed in an inclusive sense rather than an exclusive or exhaustive sense (i.e., in the sense of “including but not limited to”). The terms “connected,” “coupled,” or any variant thereof is intended to include any connection or coupling, either direct or indirect, between two or more elements. The coupling/connection can be physical, logical, or a combination thereof. For example, components may be electrically or communicatively coupled to one another despite not sharing a physical connection.

The term “based on” is also to be construed in an inclusive sense rather than an exclusive or exhaustive sense. Thus, unless otherwise noted, the term “based on” is intended to mean “based at least in part on.”

When used in reference to a list of multiple items, the word “or” is intended to cover all of the following interpretations: any of the items in the list, all of the items in the list, and any combination of items in the list.

The sequences of steps performed in any of the processes described here are exemplary. However, unless contrary to physical possibility, the steps may be performed in various sequences and combinations. For example, steps could be added to, or removed from, the processes described here. Similarly, steps could be replaced or reordered. Thus, descriptions of any processes are intended to be open-ended.

### Technology Overview

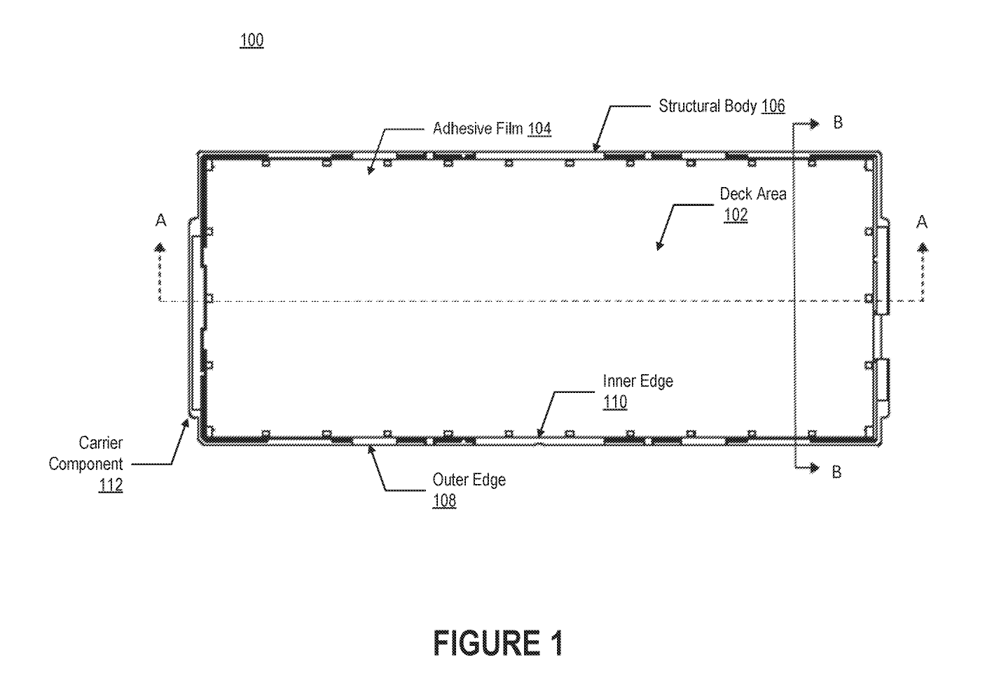

FIG. 1 depicts an example of a carrier tray 100 that includes a continuous deck area 102 laminated with an adhesive film 104. The carrier tray 100 can be designed to handle semiconductor components of different sizes (i.e., different heights, widths, lengths, etc.), as well as accommodate different fabrication plants, processes, etc. Additionally, the carrier tray 100 can be designed to maximize the density of semiconductor components for more efficient transport, shipping, storing, etc.

In some embodiments, the carrier tray 100 is designed to be compliant with Joint Electron Device Engineering Council (JEDEC), which sets standards for electrostatic discharge, handling, packing, and shipping of surface-mount devices. To comply with various JEDEC-imposed standards, the carrier tray 100 may be comprised of certain materials, manufactured in certain shapes/sizes, etc.

The shape and/or size of the carrier tray 100 may also be adapted to suit particular manufacturing, transportation, or storage needs. In some embodiments, the carrier tray 100 includes a rectangular structural body 106. In other embodiments, the carrier tray 100 includes a non-rectangular structural body in the form of, for example, a square, a parallelogram, an ellipse, etc. The size and/or the shape of the structural body 106 may be based on, for example, the design of a container in which the carrier tray 100 is to be placed. For example, rectangular structural bodies may be used in combination with containers having rectangular footprints, which are commonly used in semiconductor manufacturing, transporting, and storing processes. As another example, non-rectangular structural bodies may be used in combination with containers having non-rectangular footprints.

In some embodiments, the structural body 106 of the carrier tray 100 includes an outer edge 108 that defines the periphery of the carrier tray 100 and an inner edge 110 that defines the periphery of the deck area 102. The outer edge 108 may extend along the entire outer periphery of the carrier tray 100 in an uninterrupted manner. The inner edge 110, meanwhile, may be substantially parallel to the outer edge 108. Together, the outer edge 108 and the inner edge 110 may define opposing edges of a rim. The rim may extend around at least a portion of the deck area 102. Here, for example, the rim extends around the entire periphery of the deck area 102 of the carrier tray 100. Note, however, that the rim may include interlock component(s) to facilitate connections between adjacent carrier trays. When a semiconductor component is set within the deck area 102 of the carrier tray 100, the top surface of the deck area 102 may be substantially parallel to the bottom surface of the semiconductor component and substantially perpendicular to the outer edge of the semiconductor component. In some embodiments the rim sidewall defined by the inner edge 110 is substantially orthogonal to the bottom surface of the carrier tray 100, while in other embodiments the rim sidewall defined by the inner edge 110 has a pitch (i.e., is angled).

The structural body 106 of the carrier tray 100 can be comprised of a rigid material, such as a molded plastic or molded resin. Examples of such materials include polyethylene thermoplastics, ethylene chlorotrifluoroethylene (ECTFE), or any other material suitable for to create injection-molded objects. In some embodiments, the structural body 106 is comprised of a conductive material, such as silver, copper, aluminum, or a ceramic. In some embodiments the structural body 106 is comprised of a single material, while in other embodiments the structural body 106 is comprised of multiple materials. For example, the structural body 106 may be comprised of multiple materials that are mixed together prior to molding into its final form. As another example, the structural body 106 may be created using a first material (also referred to as a “rigid material”) able to avoid physical damage and a second material (also referred to as an “anti-static material” or a “static-dissipative material”) able to facilitate the dissipation of collected electricity. The second material may be sprayed onto the surface of the first material, adhered to the first material, or otherwise incorporated into the first material (e.g., during the manufacturing process).

As further described below, the structural body 106 may be comprised of a material known to be suitable for injection molding with the goal of producing a carrier tray 100 that is resistive to moisture and/or electricity (e.g., to prevent static electricity collection and electrostatic discharge). For example, the structural body 106 may include an anti-static material or a static-dissipative material. As another example, the structural body 106 may be comprised of a resilient material capable of protecting semiconductor components from physical damage.

In some embodiments the adhesive film 104 is laminated along a portion of the deck area 102, while in other embodiments the adhesive film 104 is laminated along the entirety of the deck area 102 (e.g., as a single continuous sheet). The adhesive film 104 may be adhesive along both sides. That is, the adhesive film 104 may have a first adhesive side in contact with the deck area 102 and a second adhesive side in contact with the bottom surface(s) of the semiconductor component(s) affixed within the deck area 102. In some embodiments, the adhesive film 104 is only adhesive along a single side (e.g., the outward-facing side to which semiconductor component(s) are secured). In such embodiments, the carrier tray 100 may include a fastening mechanism (e.g., a clasp, clip, or tab) to hold the adhesive film 104 against the top surface of the deck area 102. In some embodiments, the carrier tray 100 includes a cavity or a pre-molded area to receive the adhesive film 104. For example, the deck area 102 may include a 10-inch by 10-inch cavity. In some embodiments at least one side of the cavity is aligned with the inner edge 110 of the rim, while in other embodiments the cavity is offset from the inner edge 110 of the rim. As another example, the deck area 102 may include a series of cavities, each of which is designed to hold a separate semiconductor component. In some embodiments each cavity includes a different adhesive film, while in other embodiments a single adhesive film overlays all of the cavities.

The adhesive film 104 may be sized in such a manner to restrict subsequent movement. For example, the adhesive film 104 may be secured along at least a portion of the sidewall defined by the inner edge 110. Alternatively, the adhesive film 104 may be cut such that it does not contact the sidewall defined by the inner edge 110. Thus, the adhesive film 104 may only be in contact with the deck area 102 of the carrier tray 100.

The adhesive film 104 can be comprised of any suitable adhesive material having sufficient tackiness. For example, the adhesive film 104 may be comprised of a polymer-based adhesive. The adhesive film 104 can be mounted to the carrier tray 100 such that the adhesive film 104 is laminated along the entirety of the top surface of the deck area 102 (including any cavities, such as pre-formed, JEDEC-compliant punched cavities). In other embodiments, the adhesive film 104 may itself include cavities (also referred to as “depressions”) designed to receive semiconductor component(s). For example, the adhesive film 104 may include circular depression(s) to receive circular semiconductor components, rectangular depression(s) to receive rectangular semiconductor components, or any combination thereof.

The adhesive film 104 (also referred to as a “film tape”) can be affixed to the top surface of the carrier tray 100 as a single continuous sheet without any breaks. This can be done in several different ways, including via a lamination process, a spray process, or a co-extrusion process. In some embodiments, a top cover (not shown) is affixed to the top surface of the adhesive film 104. The top cover may be removed from the top surface of the adhesive film 104 before semiconductor component(s) are affixed to the adhesive film 104 (and thus to the carrier tray 100). Those skilled in the art will recognize that the top cover may not always be present. For example, the top cover may be unnecessary if semiconductor component(s) are to be secured to the adhesive film 104 soon after the adhesive film 104 is affixed to the top surface of the carrier tape.

The carrier tray 100 may also include one or more carrier components 112. Each carrier component 112, which may be arranged along the outer edge 108 of the carrier tray 100, may be designed to allow for easier transportation. For example, carrier component(s) 112 may be arranged along opposing sides of the carrier tray 100 to allow it (as well as any other carrier trays to which it is connected) to be transported with greater ease and efficiency. Each carrier component 112 may be formed into a shape that can be readily held (e.g., by an individual or a machine). Examples of such shapes include rectangular tabs/handles, semicircular tabs/handles, etc. More specifically, each carrier component 112 could include a handle, a latch, a tab, or some other known mechanism for assisting in the transportation of the carrier tray 100. In some embodiments the carrier component(s) 112 are separately engaged to the carrier tray 100, while in other embodiments the carrier tray 100 and the carrier component(s) 112 form a single monolithic component.

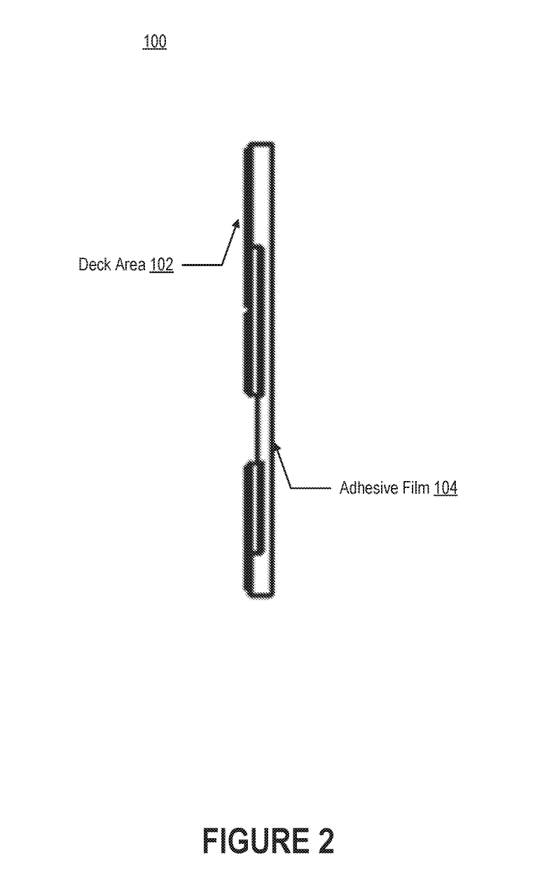

FIG. 2 illustrates a vertical section view of the carrier tray 100 taken along line B of FIG. 1. As noted above, an adhesive film 104 can be integrally mounted along the surface of the carrier tray 100. The adhesive film 204 may be secured to the carrier tray 100 such that it is substantially flush with the deck area 102 of the carrier tray 100.

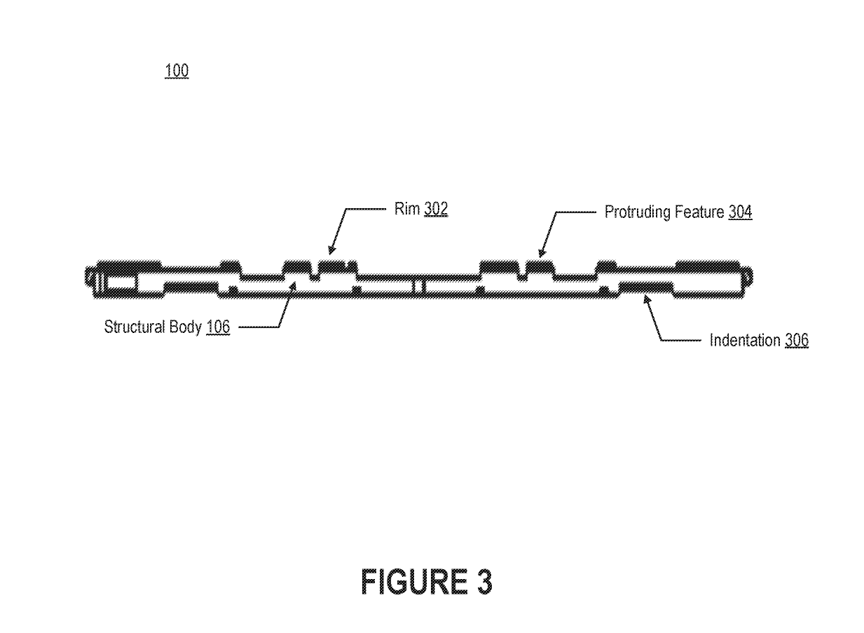

FIG. 3 illustrates a horizontal sectional view of the carrier tray 100 taken along line A of FIG. 1. As noted above, the carrier tray 100 may include a rim 302 that extends around at least a portion of the periphery of the deck area in which semiconductor component(s) are secured. In some embodiments, the rim 302 includes interlock component(s) to facilitate connections between adjacent carrier trays. As shown in FIG. 3, the interlock component(s) can include protruding features 304 and/or indentations 306 designed to complement protruding features. These interlock component(s) can be arranged along the planar surface of the rim 302, the underside of the structural body 106, or any combination thereof.

The interlock component(s) may also make the carrier tray 100 more suitable to be used in future processes. For example, when the carrier tray 100 is used for storage or transport, it may be beneficial to stack a series of carrier trays on top of one another. Therefore, having a locking mechanism would ensure that these carrier trays do not move in such a manner that would damage the semiconductor components. While the interlock component(s) represent passive locking mechanisms, those skilled in the art will recognize that more active locking mechanisms could also be used. For example, each carrier tray may include a latch that can be used to actively secure it to another carrier tray. As another example, when a mechanical device is needed to remove the semiconductor component(s) from the carrier tray 100, the interlock component(s) may serve as a support structure capable of mechanically interfacing with the mechanical device. For instance, a robotic arm may use an indentation for balancing, a protruding feature for positional reference, etc.

In some embodiments, the planar surface of the rim 302 is substantially co-planar with the top surface of the semiconductor component(s) secured within the carrier tray 100. Thus, the height of the rim 302 may be based on the thickness of the semiconductor components. In other embodiments, the planar surface of the rim 302 is higher than the top surface of the semiconductor component(s) secured within the carrier tray 100. Such a design causes a space to be formed between the top surface of each semiconductor component and the bottom surface of an upwardly adjacent carrier tray, which may limit the likelihood of damage to the semiconductor component due to an external force applied by the upwardly adjacent carrier tray.

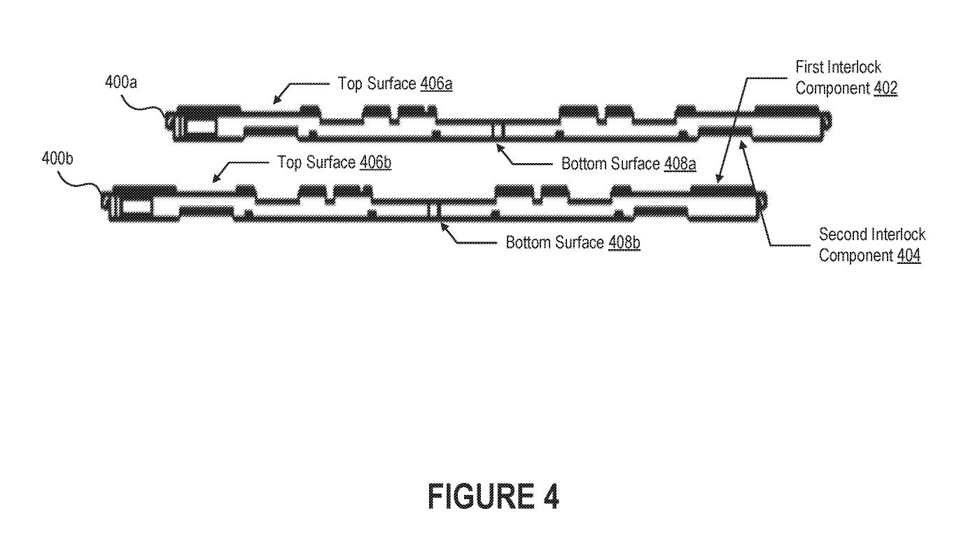

FIG. 4 includes an exploded view of multiple carrier trays 400a-b stacked for handling, transport, and/or storage of semiconductor components. A first interlock component 402 disposed along the top surface of one carrier tray 400b interfaces with a second interlock component 404 disposed along the bottom surface of another carrier tray 400a when the carrier trays 400a-b are brought within close proximity of one another.

Each carrier tray 400a-b includes a top surface 406a-b and a bottom surface 408a-b. The top surface 406a-b may be defined by the planar surface of the uppermost point of the carrier tray 400a-b. For example, the top surface 406a-b may correspond to the planar surface of the rim (i.e., while ignoring any indentations). The bottom surface 408a-b may be defined by the planar surface of the lowermost point of the carrier tray 400a-b. In some embodiments the lowermost point of the carrier tray 400a-b is the bottom surface of the structural body, while in other embodiments the lowermost point of the carrier tray 400a-b is the planar surface of an interlock component (e.g., a downwardly extending protruding feature).

As shown in FIG. 4, the bottom surface of each carrier tray may include interlock component(s) designed to engage with complementary interlock component(s) of a downwardly adjacent carrier tray. Similarly, the top surface of each carrier tray may include interlock component(s) designed to engage with complementary interlock component(s) of an upwardly adjacent carrier tray. Together, these interlock component(s) enable adjacent carrier trays to be mechanically coupled to each other without increasing the risk of harming the semiconductor component(s) stored therein.

The interlock components 402, 404 generally are of two different types. The first type of interlock component extends away from a reference surface. Examples of the first type of interlock component include protrusions, projections, pins, etc. The second type of interlock component is designed to receive an interlock component of the first type. Examples of the second type of interlock component include notches, slots, recesses, etc.

Generally, the first interlock component 402 and the second interlock component 404 are different types of interlock components. Here, for example, the first interlock component 402 is an interlock component of the first type (e.g., a protrusion), while the second interlock component is an interlock component of the second type (e.g., a notch). Accordingly, the first interlock component 402 can engage a corresponding interlock component of the second type on an upwardly adjacent carrier tray, while the second interlock component 404 can engage a corresponding interlock component of the first type on a downwardly adjacent carrier tray.

While the interlock components shown in FIG. 4 extend around the entirety of the top surfaces 406a-b and bottom surfaces 408a-b of the carrier trays 400a-b, those skilled in the art will recognize that other designs are also possible. For example, each carrier tray 400a-b may include a specified number of interlock components (e.g., one, two, four, or eight) arranged along the top surface 406a-b and/or the bottom surface 408a-b. These interlock component(s) can be positioned in different arrangements. For example, each carrier tray 400a-b could include a pair of interlock components of the first type on opposing sides of the top surface 406a-b and a pair of interlock components of the second type on opposing sides of the bottom surface 408a-b. As another example, each carrier tray 400a-b could include four interlock components equally distributed along the top surface 406a-b and four interlock components equally distributed along the bottom surface 408a-b. To allow for easier stacking, the number of interlock component(s) along the top surface 406a-b and the bottom surface 408a-b are usually the same.

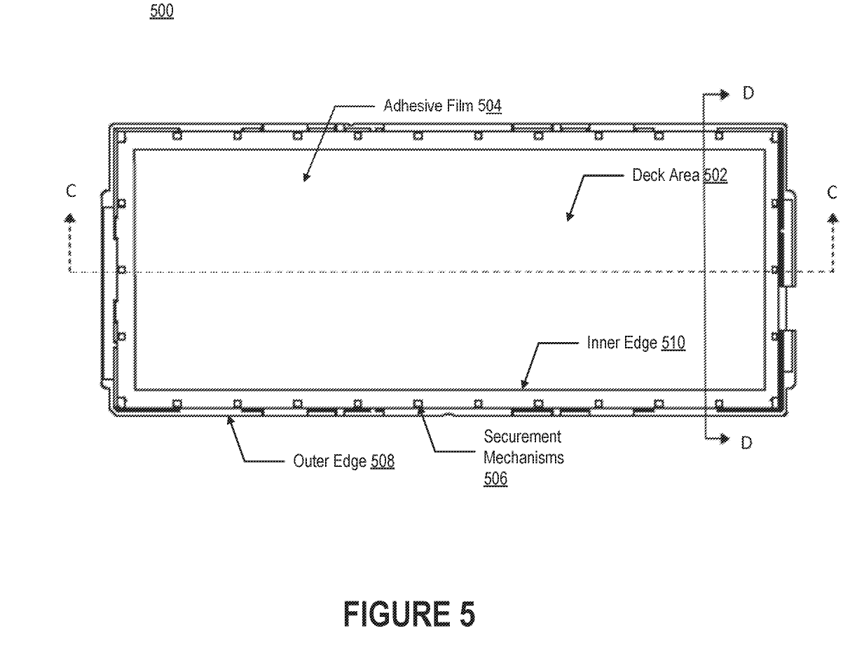

FIG. 5 includes a top plane view of a carrier tray 500 that includes a deck area 502 on which an adhesive film 504 has been mounted. In some embodiments, the adhesive film 504 is affixed to the deck area 502 using securement mechanism(s) 506 configured to grasp the adhesive film 504. For example, a series of securement mechanisms 506 designed to pinch the adhesive film 504 may be arranged along a periphery of the deck area 502. Examples of securement mechanisms include components that operate similar to paperclips, clamps, or binder clips.

In some embodiments, the adhesive film 504 is integrally secured along a central mounting portion of the carrier tray 500 such that the adhesive film conforms to the deck area 502 as defined by the inner edge 510. However, the adhesive film 504 may extend across the deck area 502 as a single continuous sheet. When a semiconductor component is secured within the deck area 502, a protruding feature disposed along the outer surface of the semiconductor component may pierce the adhesive film 504. In such embodiments, the deck area 502 may include a complementary feature (e.g., a notch) designed to receive the protruding feature of the semiconductor component.

The surface adhesion (also referred to as “tackiness”) of the adhesive film 504 holds the semiconductor component(s) in place as the carrier trays 500 is moved. For example, the adhesive film 504 can hold the semiconductor component(s) in a specified orientation during handling/transport/storage and while the semiconductor component(s) are separated/detached (e.g., manually or automatically) during a manufacturing process or a testing process. The adhesive film 504 can ensure that the semiconductor component(s) do not substantially move when the carrier tray 500 is rotated along the x-axis, y-axis, or z-axis, or moved vertically/horizontally with respect to, for example, an automatic-placement machine.

As shown in FIG. 5, the adhesive film 504 can be affixed to the deck area 502 in a single continuous sheet along the entire length of the carrier tray 500. That is, the adhesive film 504 can be affixed along the entire length of the carrier tray 500 including any cavities, such as pre-formed, JEDEC-compliant punched cavities. In some embodiments, the adhesive film 504 comprises multiple interconnected sheets. For example, a matrix of adhesive sheets can be electrically coupled by wiring or mechanically coupled by the same material as the adhesive sheets.

Generally, the adhesive film 504 does not cover the side portions disposed along the outer edge 508 of the carrier tray. Said another way, the adhesive film 504 will typically not extend up the sidewall of the rim as defined by the inner edge 510. However, in some embodiments, the adhesive film 504 does at least partially cover the sidewalls of the rim extending around the deck area 502. Together, the adhesive film 504 and the carrier tray 500 form a carrier assembly that can be used to universally transport media (e.g., singulated silicon components or silicon die of the same or different sizes) as necessary for manufacturing, shipping, and/or storing.

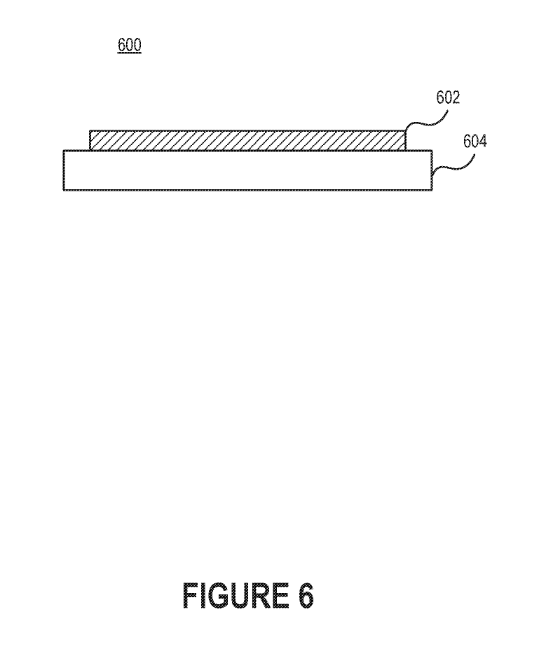

FIG. 6 includes a sectional view depicting the pre-forming of a carrier tray 600 that includes a deck area 604 and an adhesive film 602. In some embodiments, the adhesive film 602 is not perfectly flush with the deck area 604 of the carrier tray 600. For example, a protruding feature disposed along the outer surface of a semiconductor component may pierce the adhesive film 604 when interconnected with the deck area 604.

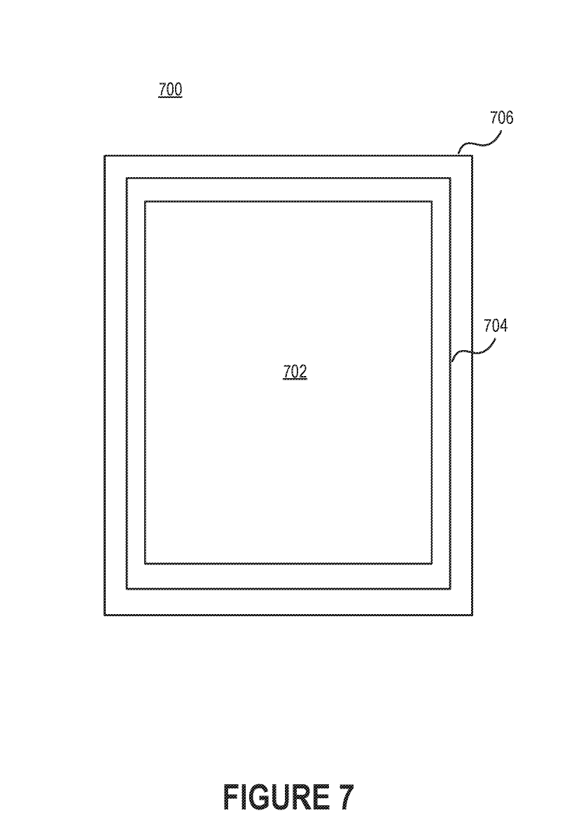

FIG. 7 includes a top plan view of a carrier tray 700 showing how an adhesive film 702 can be laminated along a deck area 704 set within a rim 706 that extends around a periphery of the carrier tray 700. In some embodiments the adhesive film 702 covers the entire deck area 704, while in other embodiments the adhesive film 702 covers a portion of the deck area 704. Here, for example, a portion of the deck area 704 is left uncovered to form a non-adhesive border.

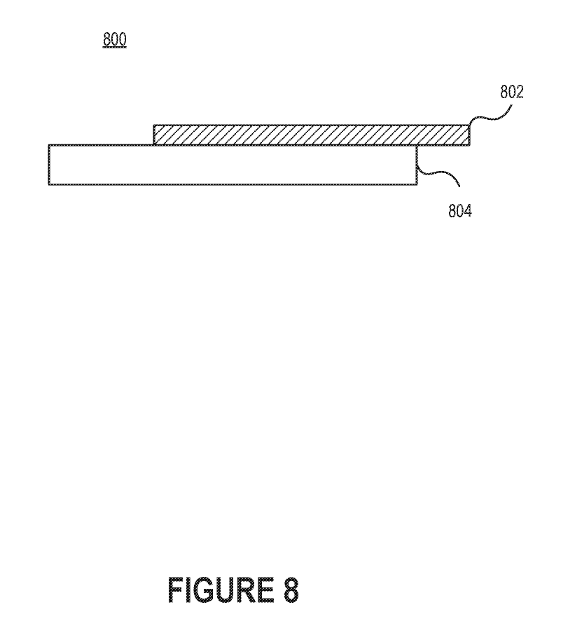

FIG. 8 includes a sectional view of the layers of a pre-formed carrier tray 800 and an adhesive film 808 that is integrally mounted along a deck area 804. More specifically, FIG. 8 depicts one example of a technique for coupling the adhesive film 806 to the deck area 804. Here, the adhesive film 802 is continuously slid onto the deck area 804 over time. For example, the adhesive film 802 may be slid into securement mechanism(s) (e.g., securement mechanisms 506 of FIG. 5). In other embodiments, the adhesive film 802 may be slid into a cavity formed along the surface of the deck area 804.

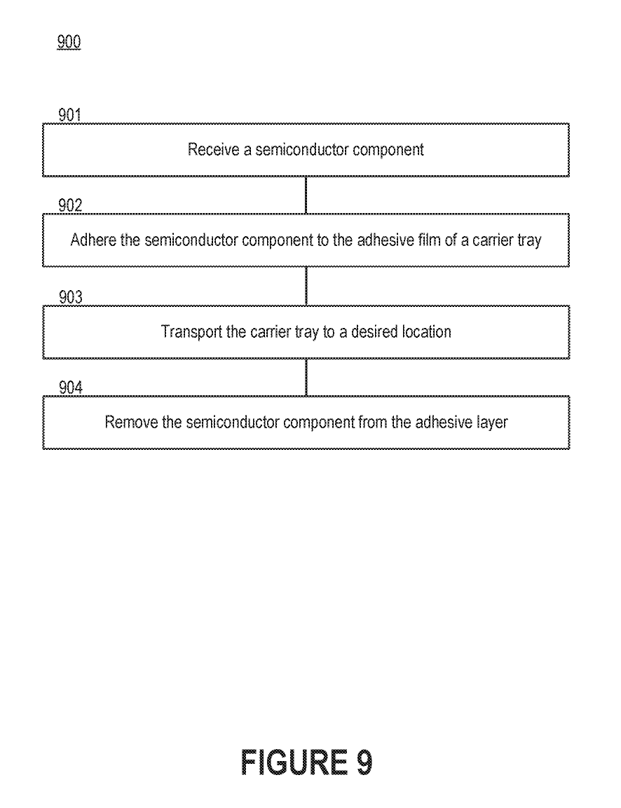

FIG. 9 is a flowchart of a process 900 for transporting semiconductor component(s) using the carrier trays described herein. Initially, an individual receives semiconductor component (step 901) that requires transport, storage, etc. Examples of semiconductor components include semiconductor wafers (e.g., singulated wafer or diced wafer), semiconductor dies (i.e., bumped die or bare die), and other electronic components used in the fabrication of integrated circuits (ICs).

Thereafter, the individual can cause the semiconductor component to be adhered to the adhesive film of a carrier tray (step 902). For example, the individual may manually secure the semiconductor component to the adhesive film or prompt an automatic-placement machine to secure the semiconductor component to the adhesive film. The semiconductor component may be positioned in a matrix pattern designed to maximize density of semiconductor components along a deck area. For example, the individual may secure the semiconductor component in a predetermined location (e.g., defined by a notch in which a protruding component of the semiconductor component is installed).

The carrier tray can then be transported to a desired location (step 903). During transport, the carrier tray can be moved along x-axis, y-axis, or z-axis without substantially moving or damaging the semiconductor component. Upon receipt of the carrier tray by an intended recipient (e.g., an IC manufacturer), the semiconductor component can be removed by simply overcoming the surface tackiness of the adhesive film (step 904). Removal may be done manually (e.g., by a human hand) or automatically (e.g., by an automatic-placement machine).

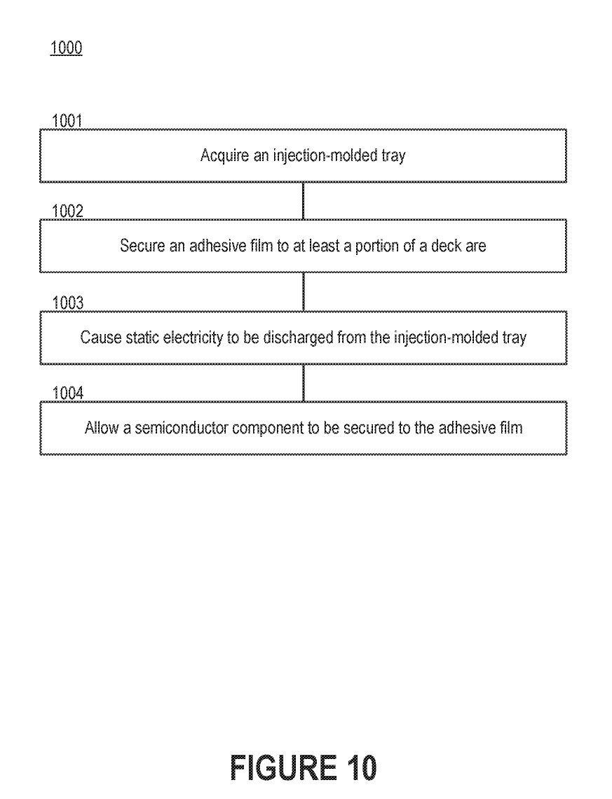

FIG. 10 is a flowchart of a process 1000 for manufacturing the carrier trays described herein. Initially, a manufacturer acquires an injection-molded tray (step 1001). In some embodiments, rather than acquire the injection-molded tray, the manufacturer creates the tray via an injection molding process. The injection-molded tray can be comprised of a rigid material, such as a molded plastic or molded resin. Examples of such materials include polyethylene thermoplastics, ECTFE, or any other material suitable for to create injection-molded objects.

The manufacturer can then secure an adhesive film to at least a portion of a deck area accessible along the top surface of the carrier tray (step 1002). For example, the adhesive film may be affixed to the entirety of the deck area as a single continuous (i.e., unbroken sheet). This can be done in several different ways, including via a lamination process, a spray process, or a co-extrusion process. In some embodiments, the adhesive film is secured against the deck area using securement mechanism(s), such as clasps. Additionally or alternatively, the adhesive film may be secured within a pre-molded cavity within the deck area. The adhesive film may have sufficient bonding strength such that is can be integrally mounted into any surface features formed in the deck area.

In some embodiments, the manufacturer causes static electricity to be discharged from the injection-molded tray (step 1003). For example, the manufacturer may discharge static electricity from the injection-molded tray by initiating contact with a grounded object. As another example, the manufacturer may discharge static electricity from the injection-molded tray by installing object(s), such as a ground plane, that will facilitate the discharge. Discharging static electricity reduces the likelihood of harming any semiconductor components stored in the carrier tray due to static shock or electricity otherwise passing through when it should not be.

Thereafter, the manufacturer can allow a semiconductor component to be secured to the adhesive film (step 1004). Semiconductor components may utilize the surface energy and/or tackiness of the adhesive film for seating attachment at a certain density (e.g., a maximum continuous density) along the deck area of the carrier tray. In some embodiments, the semiconductor component is simply secured to the top surface of the adhesive film. In other embodiments, the semiconductor component includes a protruding feature designed to mate with a recess along the deck area of the carrier tray. In such embodiments, the protruding feature may puncture the adhesive film as it enters the recess.

Unless contrary to physical possibility, it is envisioned that the steps described above may be performed in various sequences and combinations. For example, the manufacturer may acquire an injection-molded tray that already includes an adhesive film. Thus, in some instances the manufacturer may only need to secure semiconductor component(s) to the deck area of the carrier tray, and then provide the carrier tray to another entity (e.g., a manufacturer of ICs).

Additional steps could also be included in some embodiments. For example, after the semiconductor component(s) have been secured to the adhesive film, a cover tape may be used to hold the semiconductor component(s) in place. The cover tape may only be used in certain situations (e.g., long-distance transport or long-term storage) where the carrier tray is expected to undergo bumping, shaking, etc.

### Remarks

The foregoing examples of various embodiments have been provided for the purposes of illustration and description. These examples are not intended to be exhaustive. Many variations will be apparent to one skilled in the art. Certain embodiments were chosen in order to best describe the principles of the technology introduced herein, thereby enabling others skilled in the relevant art to understand the claimed subject matter, the various embodiments, and the variations that may be suited to particular uses.

The language used in the specification has been principally selected for readability and instructional purposes. It may not have been selected to delineate or circumscribe the subject matter. Therefore, it is intended that the scope of the technology be limited not by this specification, but rather by any claims that issue based hereon. Accordingly, the disclosure of the technology is intended to be illustrative (rather than limiting) of the scope of the technology, which is set forth in the following claims.

What is claimed is:

1. A carrier tray assembly comprising:
a rigid tray that includes
a deck area having a substantially flat surface for receiving semiconductor components, and
a rim that extends around at least a portion of a periphery of the deck area;
an adhesive film affixed to the substantially flat surface of the deck area,
wherein the adhesive film includes a tacky upper surface for securing the semiconductor components to the deck area.

2. The carrier tray assembly of claim 1, wherein the rigid tray is formed as a single component during an injection molding process.

3. The carrier tray assembly of claim 1, wherein the rigid tray is comprised of polyethylene thermoplastic.

4. The carrier tray assembly of claim 1, wherein the adhesive film is laminated to the substantially continuous surface of the deck area as a single continuous sheet during a lamination process.

5. The carrier tray assembly of claim 1, wherein the adhesive film aids in the securement of the semiconductor components to the deck area in a predetermined arrangement that enables the semiconductor components to be separately pulled away from the adhesive film.

6. The carrier tray assembly of claim 5, wherein the carrier assembly is designed such that electrical current is able to flow from the rigid tray to an electrical ground.

7. The carrier tray assembly of claim 1, wherein the adhesive film is comprised of a polymer-based material.

8. The carrier tray assembly of claim 1, wherein a height of the rim is based on a thickness of the semiconductor components.

9. The carrier tray assembly of claim 1, further comprising:
a carrier component extending outward from the rim of the rigid tray.

10. The carrier tray assembly of claim 1, further comprising:
an interlock component arranged along a top surface of the rim,
wherein the interlock component is designed to engage a corresponding interlock component arranged along a bottom surface of an upwardly adjacent carrier tray assembly.

11. A method for transporting a semiconductor component, the method comprising:
acquiring a rigid carrier tray that includes a deck area on which semiconductor components are to be secured;
securing an adhesive film to at least a portion of the deck area as a single continuous sheet,
wherein the adhesive film comprises a tacky upper surface; and
adhering a semiconductor component to the tacky upper surface of the adhesive film.

12. The method of claim 11, further comprising:
forming a cavity for receiving a protruding feature of the semiconductor component into a top surface of the deck area.

13. The method of claim 12, wherein said adhering comprises:
engaging the protruding feature of the semiconductor component and the cavity of the rigid carrier tray.

14. The method of claim 13, wherein said engaging causes the protruding feature of the semiconductor component to puncture the adhesive film.

15. The method of claim 11, wherein the adhesive film comprises multiple adhesive sheets.

16. The method of claim 15, wherein the adhesive sheets are interconnected such that electrical current is able to flow between the adhesive sheets.

17. The method of claim 11, wherein the adhesive film comprises a depression to receive the semiconductor component.

18. The method of claim 11, wherein the semiconductor component is one of multiple semiconductor components that are adhered to the tacky upper surface of the adhesive film, and wherein the multiple semiconductor components are arranged in a predetermined pattern.

19. An apparatus for housing semiconductor components, the apparatus comprising:
at least two carrier tray assemblies configured to transport semiconductor components, each carrier tray assembly of the at least two carrier tray assemblies including:
a rigid tray having a substantially flat deck area,
an adhesive film affixed to the substantially flat deck area,
wherein the adhesive film includes a tacky upper surface for securing the semiconductor components to the rigid tray,
a first interlock component arranged along a top surface of the rigid tray,
wherein the first interlock component is configured to engage a corresponding interlock component on an upwardly adjacent carrier tray assembly, and
a second interlock component arranged along a bottom surface of the rigid tray,
wherein the second interlock component is configured to engage a corresponding interlock component on a downwardly adjacent carrier tray assembly.

20. The apparatus of claim 19, wherein the at least two carrier tray assemblies are vertically interlocked with one another.
